(19) United States
(12) Patent Application Publication
(10) Pub. No.: US 2026/0013170 A1
(43) Pub. Date: Jan. 8, 2026

(54) N-POLAR HEMT STRUCTURES WITH N+ CONTACT LAYERS

(71) Applicant: MONDE Wireless Inc., Goleta, CA (US)

(72) Inventors: Brian ROMANCZYK, Goleta, CA (US); Matthew GUIDRY, Goleta, CA (US); Pawana SHRESTHA, Goleta, CA (US)

(21) Appl. No.: 19/104,997

(22) PCT Filed: Oct. 17, 2023
(86) PCT No.: PCT/US2023/035316

§ 371 Date: Feb. 19, 2025

Related U.S. Application Data
(60) Provisional application No. 63/416,738, filed on Oct. 17, 2022.

(51) Int. Cl. H10D 30/47; H10D 62/85

(52) U.S. Cl. CPC H10D 30/476; H10D 62/8503

(57) ABSTRACT

N-polar HEMT structures and methods of forming HEMT structures. An example semiconductor device includes a III-N material structure, comprising: a III-N backbarrier layer; a III-N channel layer over an N-face of the III-N backbarrier layer; and an n+ III-N etch stop layer over an N-face of the III-N channel layer. The semiconductor device includes: a gate region between a source region and a drain region; a source contact over the n+ III-Netch stop layer in the source region; a drain contact over the n+ III-N etch stop layer in the drain region; a 2DEG in the III-N channel layer adjacent to an interface between the III-N channel layer and the III-N backbarrier layer; a channel recess etched through the n+ III-N etch stop layer between the source region and the drain region; and a gate recess in the channel layer and a gate contact in the gate recess.

### CROSS-REFERENCE TO RELATED APPLICATIONS

This application claims benefit of U.S. Provisional Application Ser. No. 63/416,738, filed on Oct. 17, 2022, the disclosure of which is incorporated herein by reference in its entirety.

### TECHNICAL FIELD

The current disclosure relates to semiconductor devices and in particular to N-polar HEMT Structures with n+ contact layers.

### BACKGROUND

III-Nitride semiconductor devices such as III-N high electron mobility transistors (HEMTs) are commonly formed from a III-N material structure grown in a group-III polar orientation (i.e., in the [0 0 0 1] direction) on a substrate where a III-N barrier layer is formed over a III-N channel layer. In a nitrogen-polar (N-polar) III-N HEMT device (i.e., a device in which III-N layers are oriented in the [0 0 0 −1] direction over a substrate), a III-N channel layer (i.e., a layer containing a 2DEG channel) is formed over a III-N barrier layer (hence in an N-polar III-N HEMT the barrier layer is often referred to as a “backbarrier”).

N-polar HEMT structures with in-situ n+ have been previously described with two primary variations. In some examples, the in-situ n+ layer was etched down (“channel recess”) to a UID GaN channel and a gate was placed on this etched surface. In some other examples, the channel recess is etched and then a second recess etch is used that stops on an AlGaN etch stop layer for the “gate recess”. The AlGaN etch stop layer for the gate recess allows for accurate control of the gate electrode to channel distance; however, it introduces an electron barrier in the contact regions of the devices which reduces the effectiveness of having an in-situ n+ GaN contact layer.

### SUMMARY

This document describes N-polar HEMT structures with recessed gates and n+ source and drain contact layers wherein cross-sections taken parallel to the gate width have the gate electrode sitting on a planar surface, i.e., wherein the gate electrode is on a planar surface when viewed in the direction along the gate-width. An example semiconductor device includes a III-N material structure, comprising: a III-N backbarrier layer; a III-N channel layer over an N-face of the III-N backbarrier layer; and an n+ III-N etch stop layer over an N-face of the III-N channel layer. The semiconductor device includes: a gate region between a source region and a drain region; a source contact over the n+ III-N etch stop layer in the source region; a drain contact over the n+ III-N etch stop layer in the drain region; a 2DEG in the III-N channel layer adjacent to an interface between the III-N channel layer and the III-N backbarrier layer; a channel recess etched through the n+ III-N etch stop layer between the source region and the drain region; and a gate recess in the channel layer and a gate contact in the gate recess.

### BRIEF DESCRIPTION OF DRAWINGS

FIGS. 1A-1E illustrate an example semiconductor device 100 that is an N-polar HEMT having a gate electrode on a substantially planar surface when viewed in the direction along the gate-width.

FIG. 2 is a cross-sectional view of an example epitaxial structure.

FIGS. 3A-3E show starting epitaxial structure.

FIGS. 4A-4E illustrate forming an etch mask to remove n+ contact layer in regions outside of the source and drain contact regions.

FIGS. 5A-5E illustrate etching the n+ contact layer, stopping in the channel layer, and removing the etch mask.

FIGS. 6A-6E illustrate masking the active region for the isolation process.

FIGS. 7A-7E illustrate implanting ions into the non-active region to remove the 2deg and isolate the device.

FIGS. 8A-8E illustrate forming a mask to define the gate recess.

FIGS. 9A-9E illustrate etching the gate recess.

FIGS. 10A-10E illustrate depositing gate metal and removing the etch mask from the gate recess.

FIG. 11 illustrates depositing source and drain contact metal across several cutlines.

FIGS. 12A-12E illustrate depositing interconnect metal.

FIGS. 13A-13E show the starting epitaxial structure.

FIGS. 14A-14E illustrate forming a regrowth mask that protects the regions near the active area of the FET except for over the source and drain contact regions.

FIGS. 15A-15E illustrate regrowing the n+ GaN contact layer and removing the regrowth mask.

FIG. 16 shows an epitaxial structure comprising an n+ layer as an etch stop.

FIGS. 17A-17E illustrate the process flow by showing the device structure at various stages of the process.

FIG. 18 shows an epitaxial structure that can be used to create a semiconductor device using such a stop layer.

FIG. 19 shows a structure with added doping underneath the AlGaN barrier.

FIG. 20 shows a structure with a UID spacer layer.

FIG. 21 illustrates the AlGaN etch stop options with band diagrams.

FIG. 22 illustrates a device structure having a thin n+ layer in the access regions.

FIGS. 23A-23E show an alternative device fabricated from the structure shown in FIG. 16.

FIGS. 24A-24E show a device fabricated from the structure shown in FIG. 19.

FIGS. 25A-25E show a device fabricated from the structure shown in FIG. 20

### DETAILED DESCRIPTION

This document describes N-polar HEMT structures with recessed gates and n+ source and drain contact layers wherein cross-sections taken parallel to the gate width have the gate electrode sitting on a planar surface, i.e., wherein the gate electrode is on a planar surface when viewed in the direction along the gate-width. As used herein, the terms III-Nitride or III-N materials, layers, devices, etc., refer to a material or device comprised of a compound semiconductor material according to the stoichiometric formula ScᵥB_{w}AlₓIn_{y}Ga_{z}Na(D)_{b}, where v+w+x+y+z is about 1, 0≤v≤1, 0≤w≤1, 0≤x≤1, 0≤y≤1, 0≤z≤1, a+b is about 1, 0.9<a≤1,0≤b<0.1, and (D) is any group-V element other than nitrogen.

In forming N-polar III-N HEMTs, it can be useful to place an n+ contact layer (typically n+ GaN) beneath the source and drain contacts. However, this creates some complications in device fabrication. Specifically, every device may need to be electrically isolated from the rest of the wafer. This is typically achieved by either etching away the surrounding material (or at least the portion that would otherwise contain the device channel), or by ion implanting the surrounding material to render it insulating. In general, the n+ contact layer can be an n-type III-N layer over an N-face of the III-N channel layer having a donor concentration that is, for example, at least 10¹⁸ cm⁻³

Devices with an n+ contact layer will generally have the layer formed over the entire wafer (it will be epitaxially grown along with the rest of the active semiconductor layers) and then patterned in the active region of the device to remove it from everywhere other than the source and drain regions. In the surrounding non-active region, if there exists an n+ layer, then ion implantation will not render this region sufficiently insulating.

Thus the next step is to etch away the n+ material in the non-active region, and then either (a) keep etching through the channel layer or (b) ion implant the remaining material in the non-active region. Either way, because the non-active region was etched to remove the n+ layer, a step will exist between the active and non-active regions. The gate electrode that is subsequently deposited must stretch across the entire width of the active region and over this step into the non-active region in order for the device to operate properly. However, passing the gate over this step has been shown to create a failure mode for the device. It would therefore be useful to have a device that includes n+ contact layers and for which the gate lies on a surface that is co-planar in both the active and non-active regions (i.e., lacking such a step).

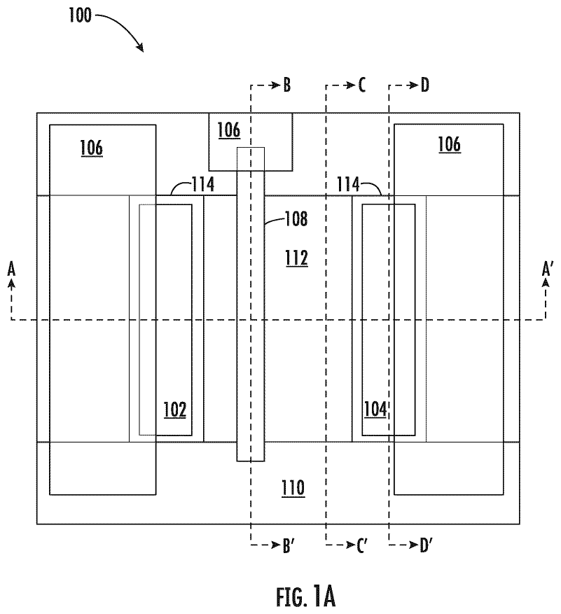

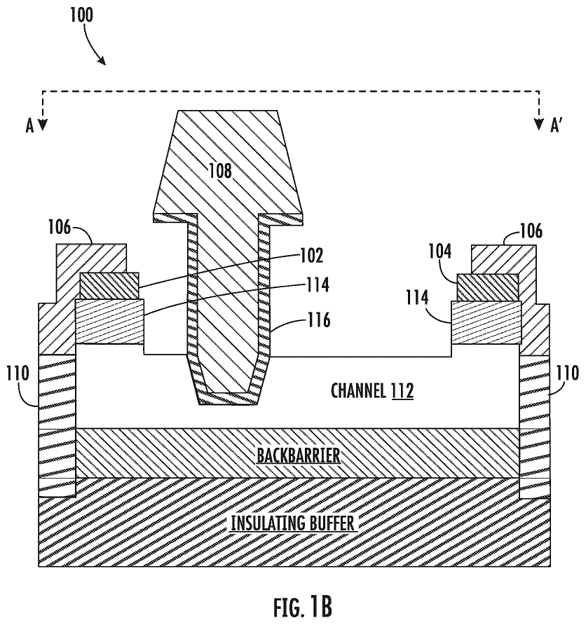

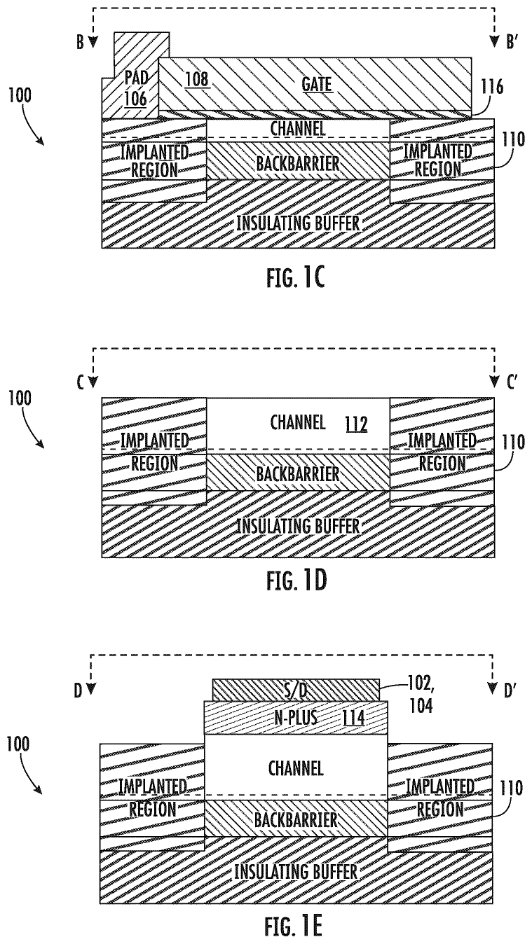

FIGS. 1A-1E illustrate an example semiconductor device 100 that is an N-polar HEMT having a gate electrode on a substantially planar surface when viewed in the direction along the gate-width.

FIG. 1A is a plan view of the device 100. The device 100 includes source ohmic metal 102, drain ohmic metal 104, interconnect metal 106, and gate metal 108. The device 100 includes an isolated region 110, for example, formed by ion implantation. The device 100 includes an active channel 112 and n+ GaN contact layers 114.

Various cutlines are drawn representing different views of the device structure. Cutline A-A′ represents the cross-section of the device showing the device in the direction of current flow. FIG. 1B illustrates the structure of the device 100 along cutline A-A′. The remaining cut lines are taken in the direction perpendicular to current flow in the device. FIG. 1B shows an optional gate dielectric 116 that underlies some or all of the gate metal 108.

Cutline B-B′ is taken through the middle of the gate electrode at the base of the gate recess etch. FIG. 1C illustrates the structure of the device 100 along cutline B-B′. Cutline C-C′ is taken through the middle of the access region on the drain side of the device 100. FIG. 1D illustrates the structure of the device 100 along cutline C-C′. Cutline D-D′ is taken through the drain contact region showing the n+ contact layer and ohmic metals. FIG. 1E illustrates the structure of the device 100 along cutline D-D′.

Referring back to FIG. 1A, showing the device 100 along cutline B-B′, the base of the gate 108 is on a substantially planar surface. The surface is “substantially” planar in that the base of the gate 108 is on a planar surface that may not be perfectly planar due to ordinary manufacturing defects. The gate 108 does not cross over an etched sidewall, which can be useful, e.g., to avoid a non-uniformity under the gate 108 that can be a point of leakage and cause failures. The gate 108 extends beyond the active channel into the isolated regions 110 without a step.

FIG. 2 is a cross-sectional view of an example epitaxial structure that can be used to obtain the device 100 shown in FIGS. 1A-1E. The epitaxial structure includes an in-situ n+ contact layer. This document describes two example methods to obtain the device 100 shown in FIGS. 1A-1E.

A first example process flow for fabrication involves subtractive removal of the n+ layer. Starting from the epitaxial structure of FIG. 2, the following steps can be performed:
1. Perform a channel recess etch that, in addition to removing the n+ contact layer between the source and drain, also removes the same amount of material in the region to be isolated leaving behind n+ only in the source and drain contact regions of the device.
2. With the n+ GaN removed from the regions to be isolated, the non-active channel is rendered insulating by ion implantation.
3. The gate recess etch is then performed, etching both the implanted region and active channel at the same time.
4. Deposition of gate metal and source and drain metal completes the device fabrication.

This process takes advantage of the implanted GaN etching at the same rate as the non-implanted GaN. Depending on conditions used this may not be always be the case; if the etch rates are different than a step will develop. This can be addressed by switching the order of steps 2 and 3 above by first etching the gate recess and then implant isolating the structure after the etching is completed.

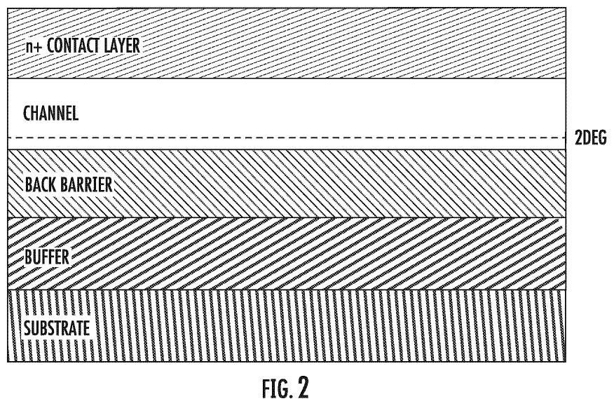

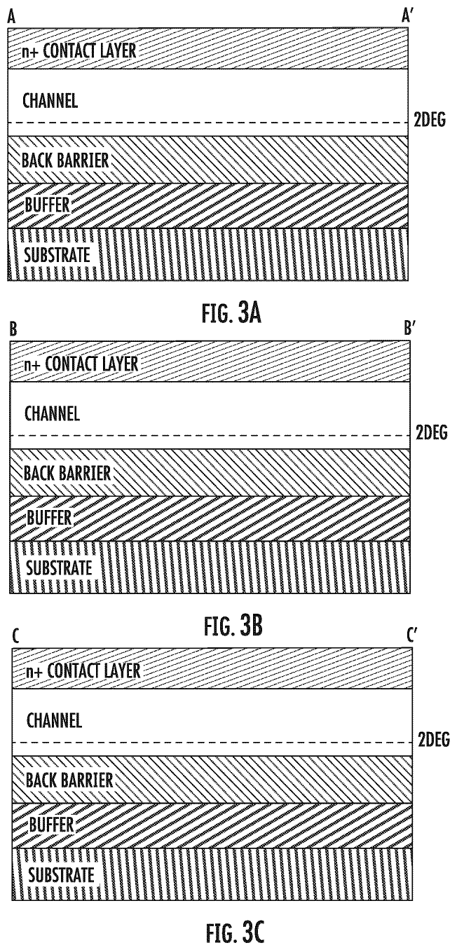

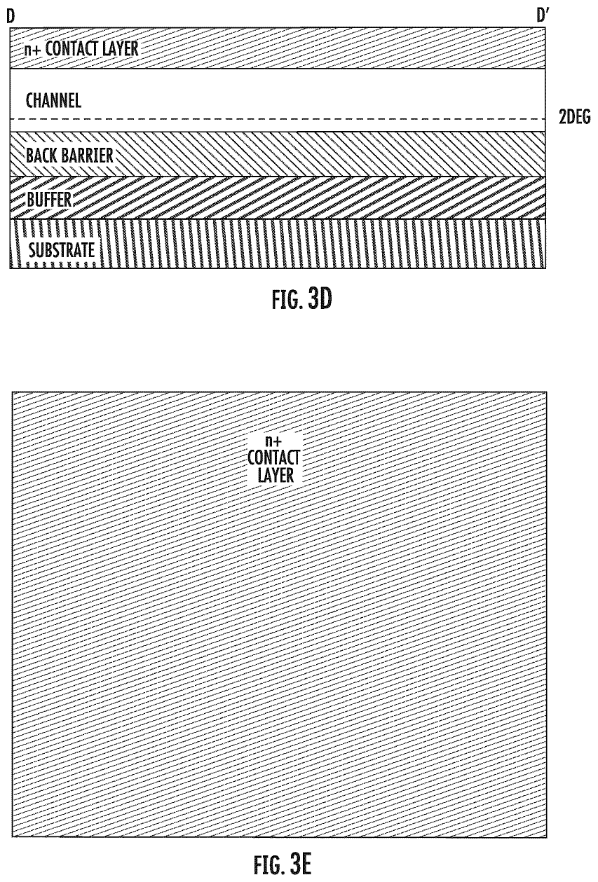

FIGS. 3A-12E illustrate the device in various stages of the fabrication process. The same cutlines from FIGS. 1A-1E are used to illustrate the device structure.

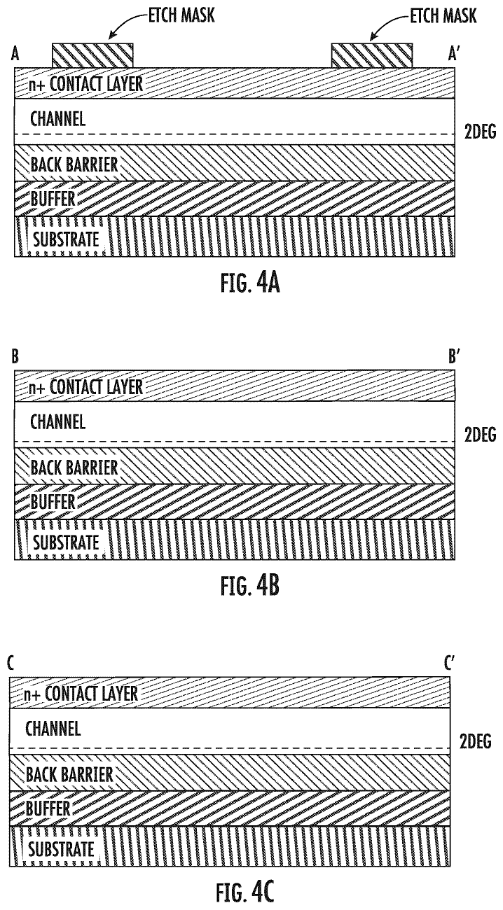

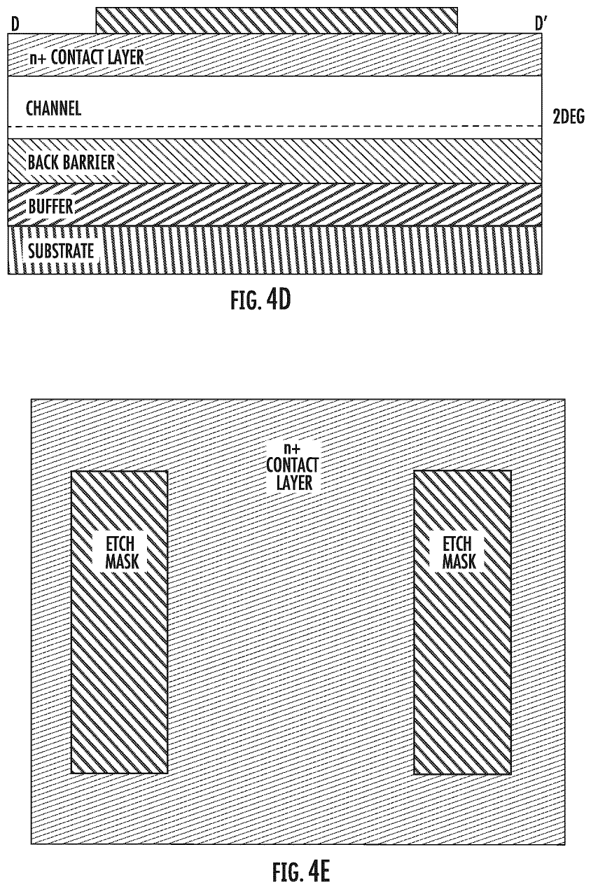

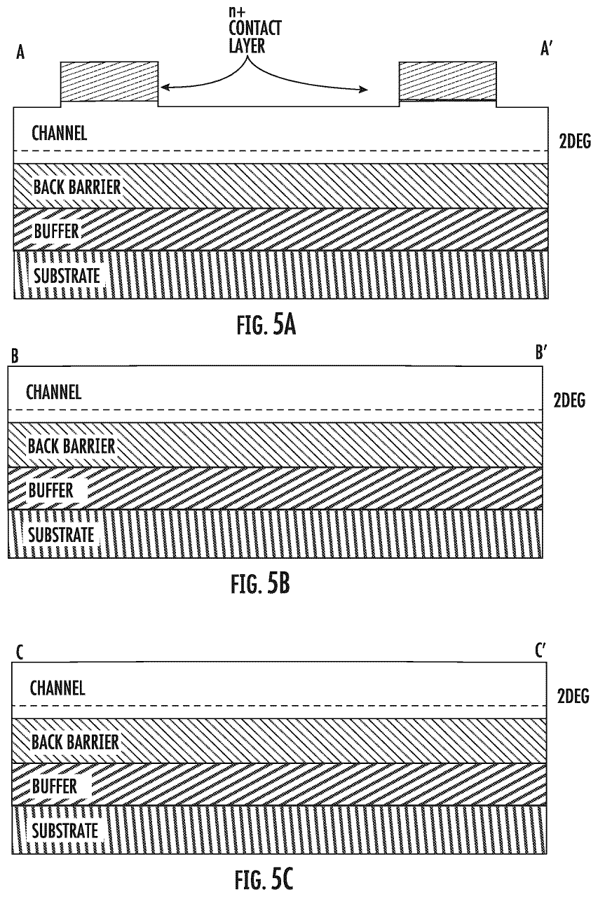

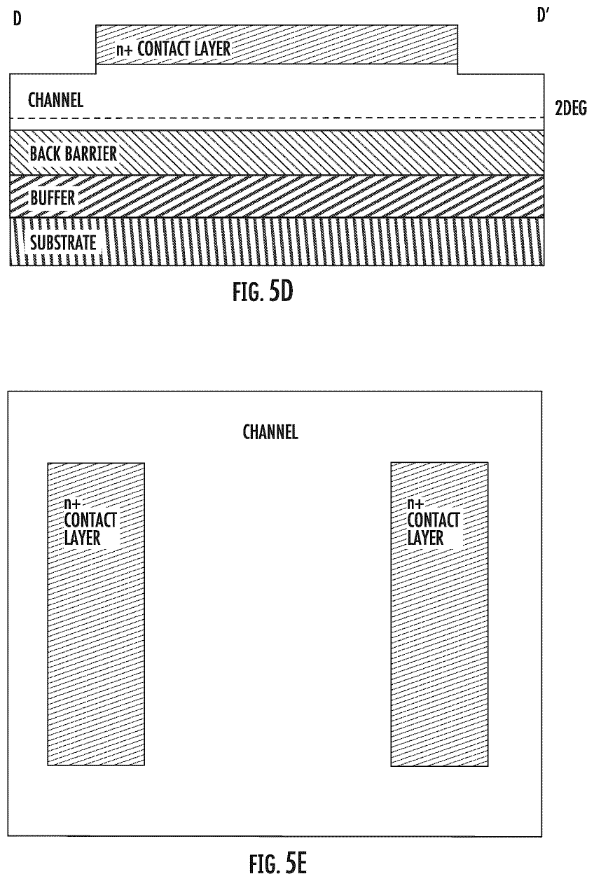

FIGS. 3A-3E show starting epitaxial structure. FIGS. 4A-4E illustrate forming an etch mask to remove n+ contact layer in regions outside of the source and drain contact regions. FIGS. 5A-5E illustrate etching the n+ contact layer, stopping in the channel layer, and removing the etch mask.

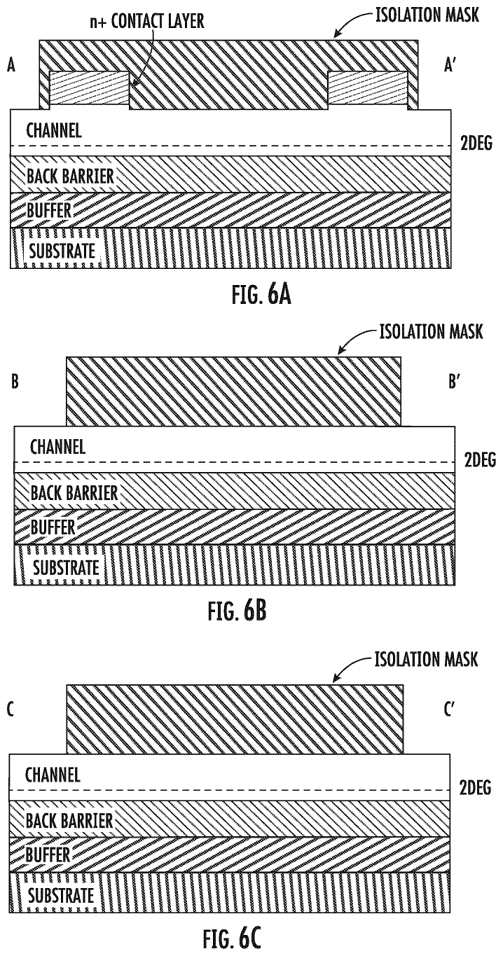

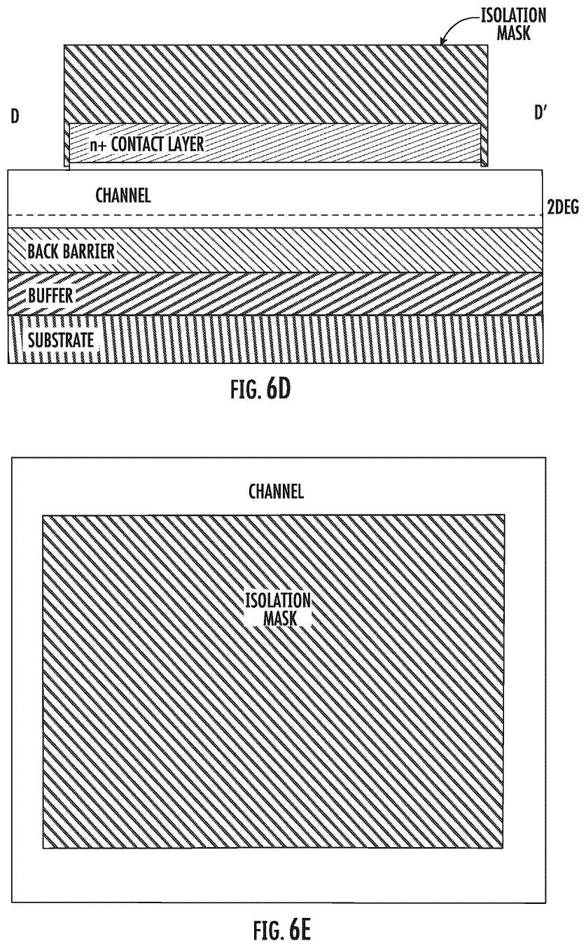

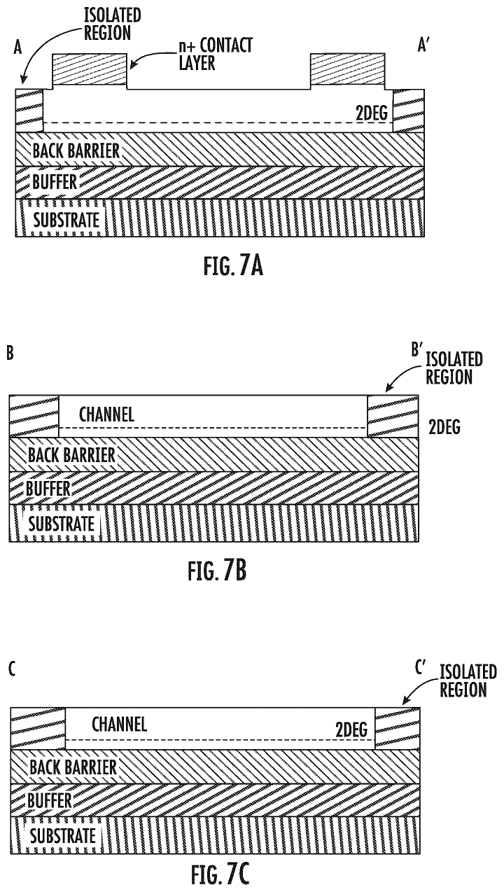

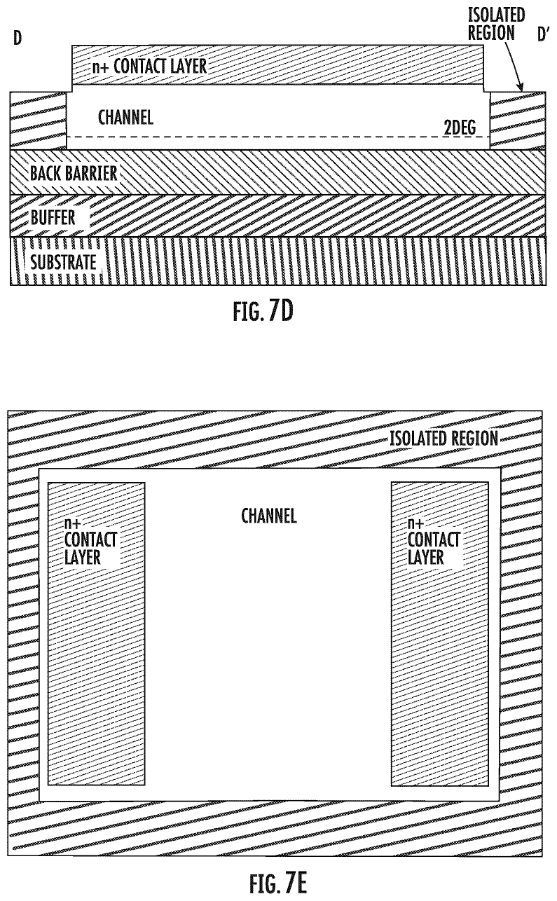

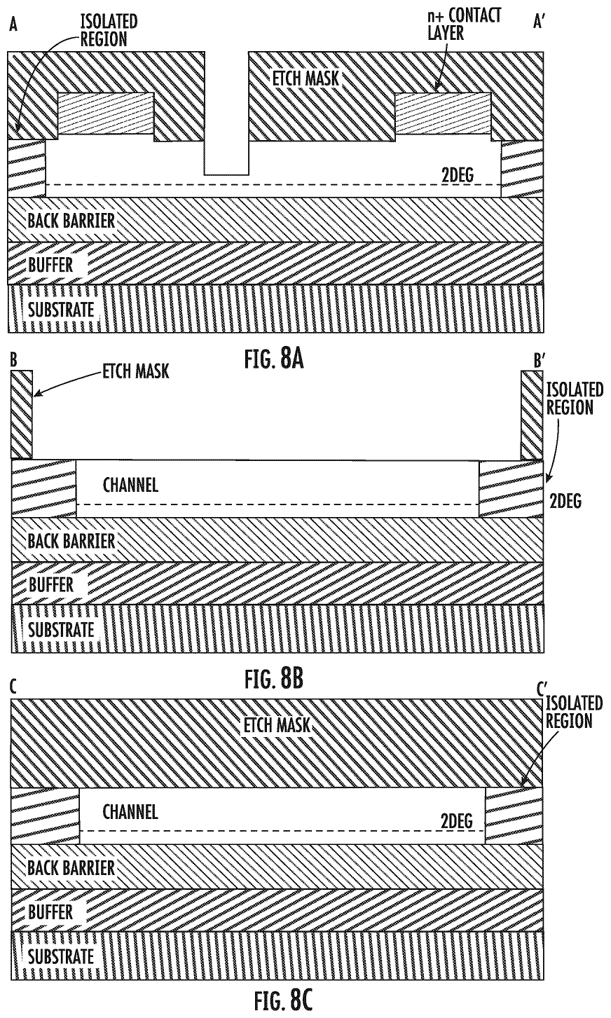

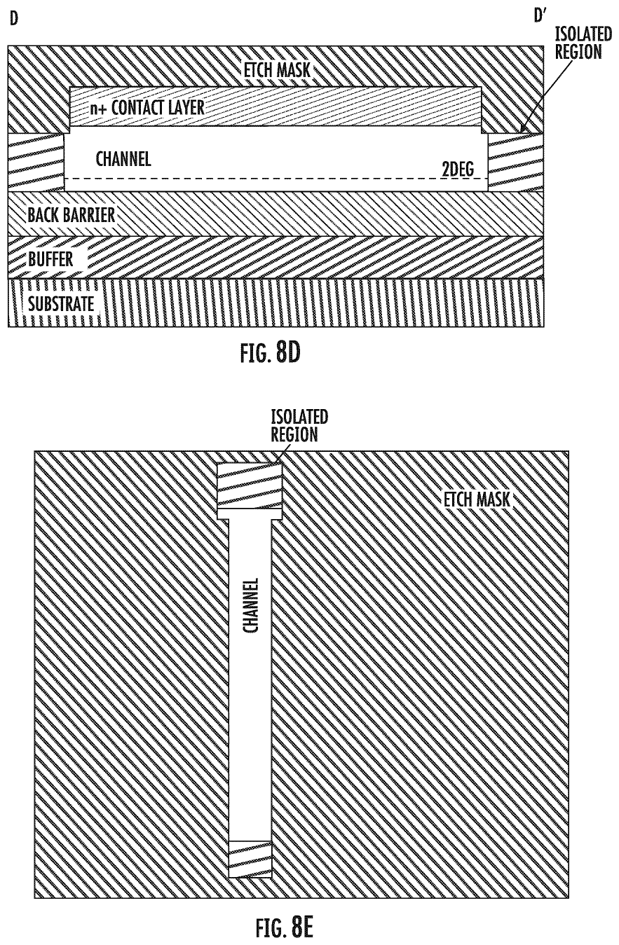

FIGS. 6A-6E illustrate masking the active region for the isolation process. FIGS. 7A-7E illustrate implanting ions into the non-active region to remove the 2deg and isolate the device. FIGS. 8A-8E illustrate forming a mask to define the gate recess.

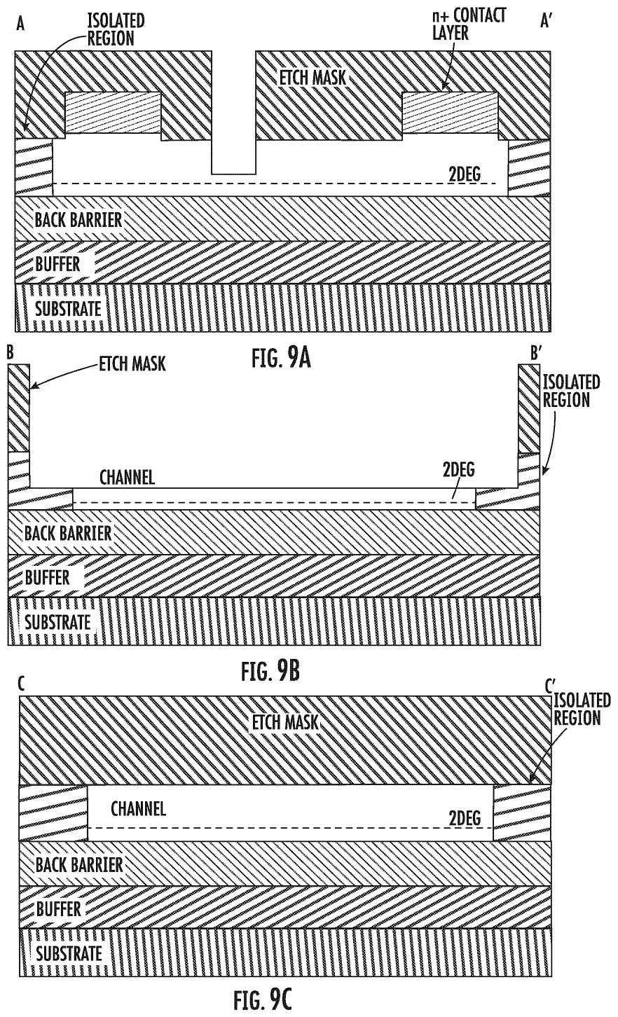

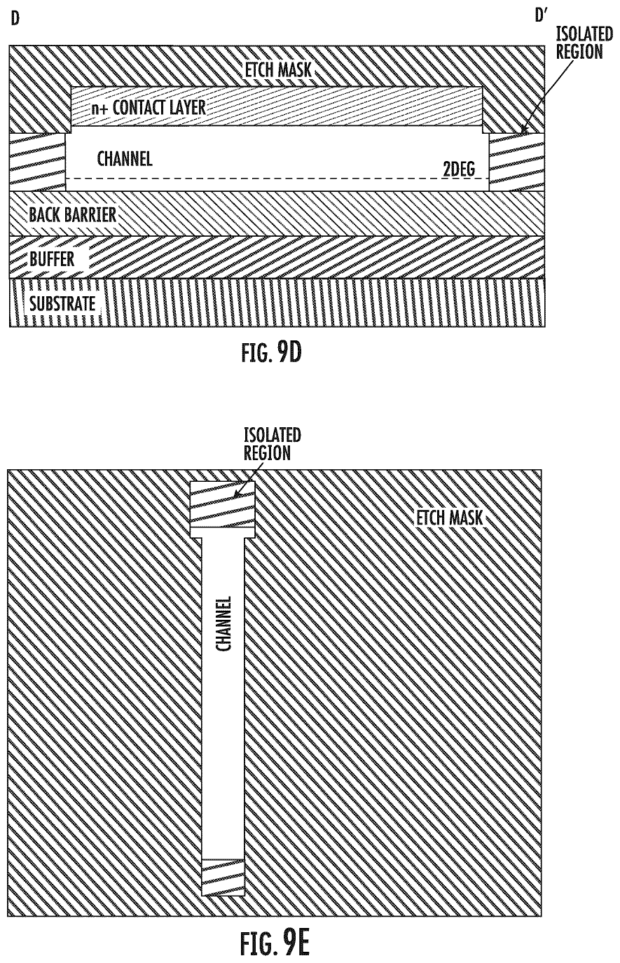

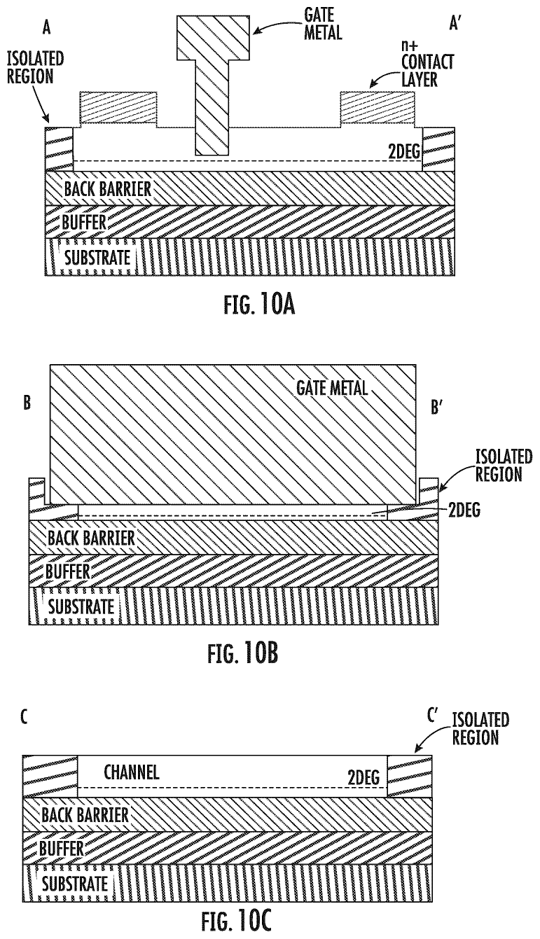

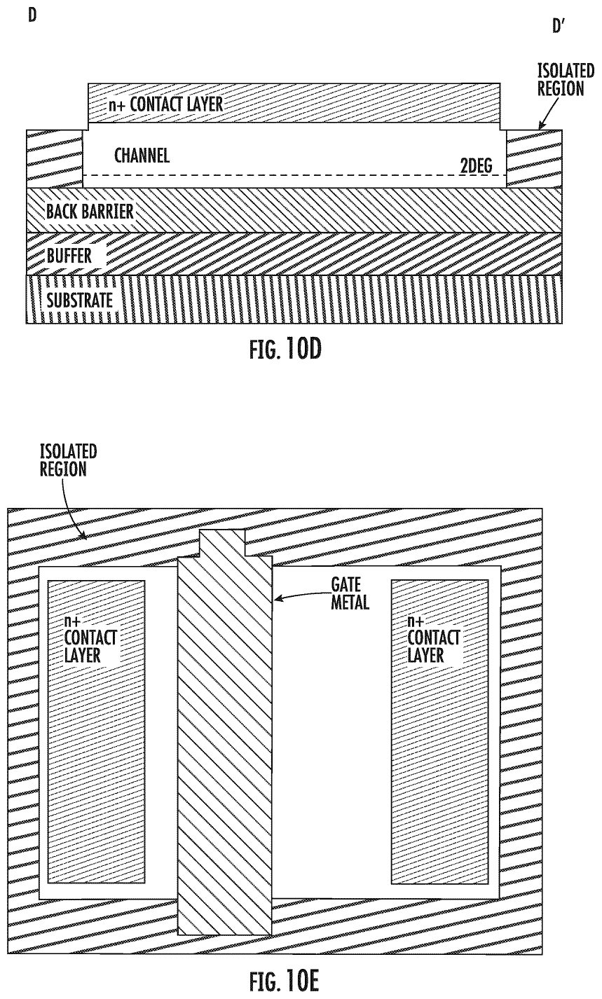

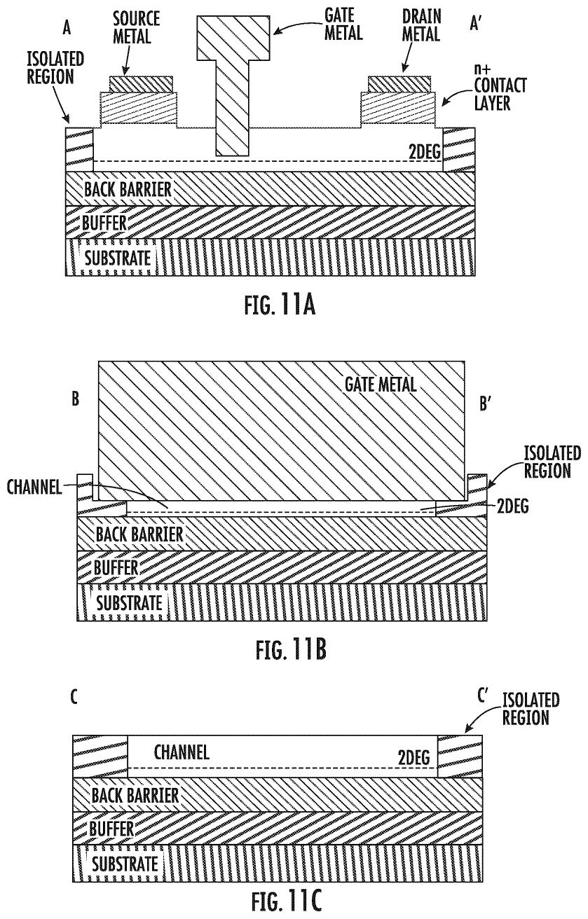

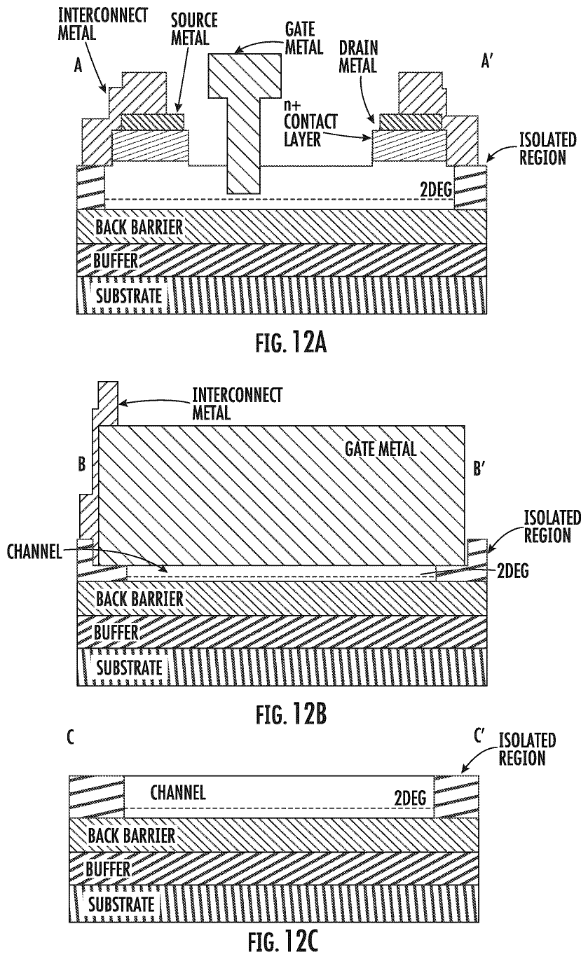

FIGS. 9A-9E illustrate etching the gate recess. FIGS. 10A-10E illustrate depositing gate metal and removing the etch mask from the gate recess. Optionally, gate dielectric can be deposited. FIG. 11 illustrates depositing source and drain contact metal across several cutlines.

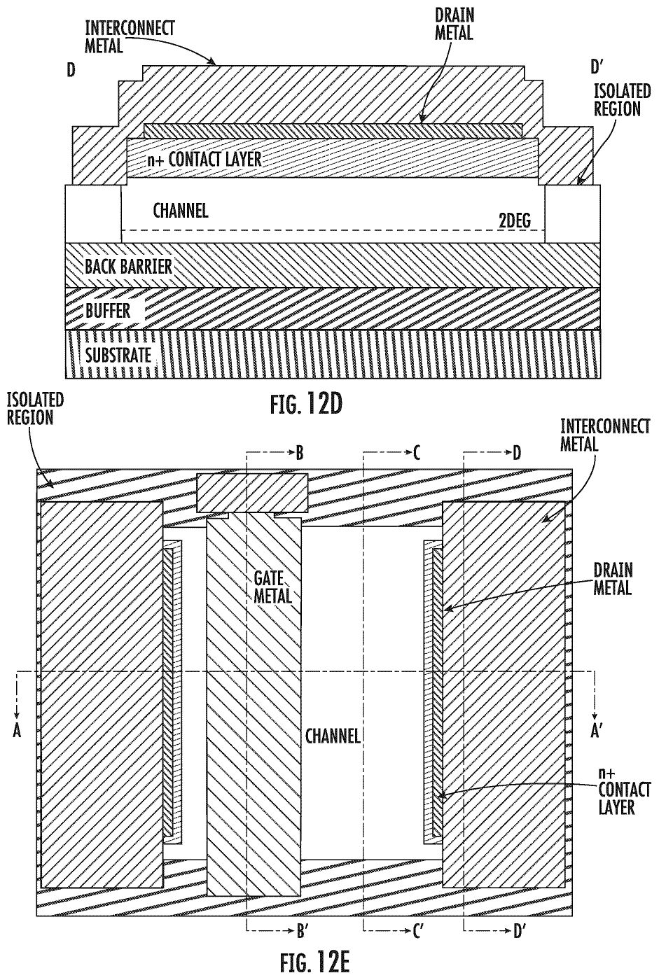

FIGS. 12A-12E illustrate depositing interconnect metal. The resulting device has a planar isolated gate structure for a recessed gate N-polar HEMT with an n+ contact layer.

Another example method for fabricating the device 100 of FIGS. 1A-1E involves regrowth of the n+ contact layer. With regrowth occurring on a wafer where a large fraction of the surface is masked, growth rates may not be as well controlled compared to some conventional systems. However the same structure can be obtained by using selective area growth, regrowing the n+ GaN in the region around the active region only where it needs to be under the source and drain contacts. In summary, the method of fabricating includes:
1. Define a regrowth hard mask (e.g., SiO2) that masks both the active channel as well as the region surrounding the perimeter of the FET such that the regrowth near the FET occurs only in locations where it does not need to be removed later in the process. In some examples, some regions of n+ may be included in other regions of the wafer, for example, to form resistors as part of a circuit or to just fill in area to make the selective area growth workable.
2. Etch any GaN and AlGaN cap layers exposing the channel layer. The GaN and AlGaN cap layers are optional layers, and, if they are not present, then this etching step need not be performed.
3. Regrow n+ GaN
4. Implant isolate the FETs
5. Perform the gate recess
6. Deposit Gate and S/D ohmic metal to complete the FET

In some examples, it may be useful to switch steps 4 and 5 in the case that the gate recess etch process has different etch rates for implanted and non-implanted layers.

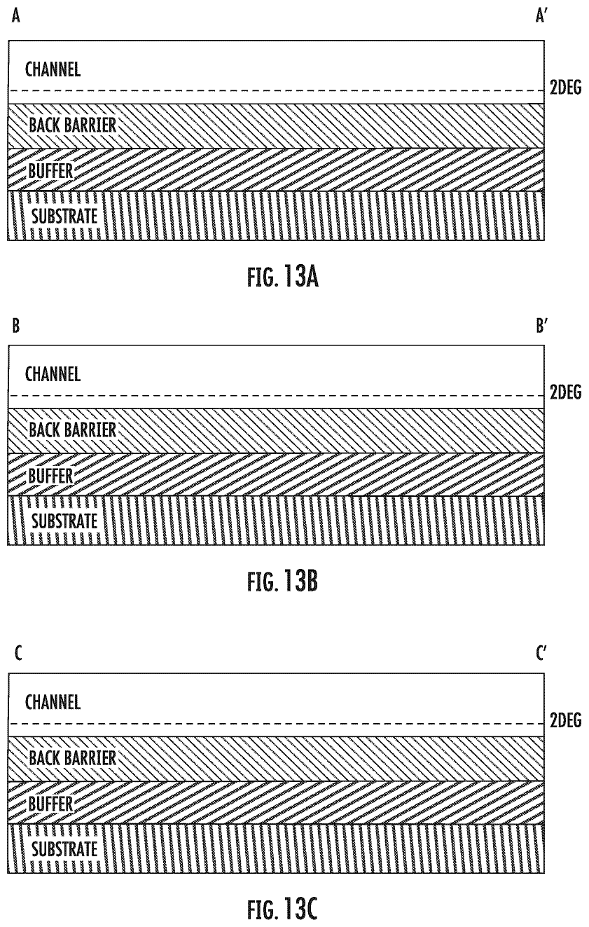

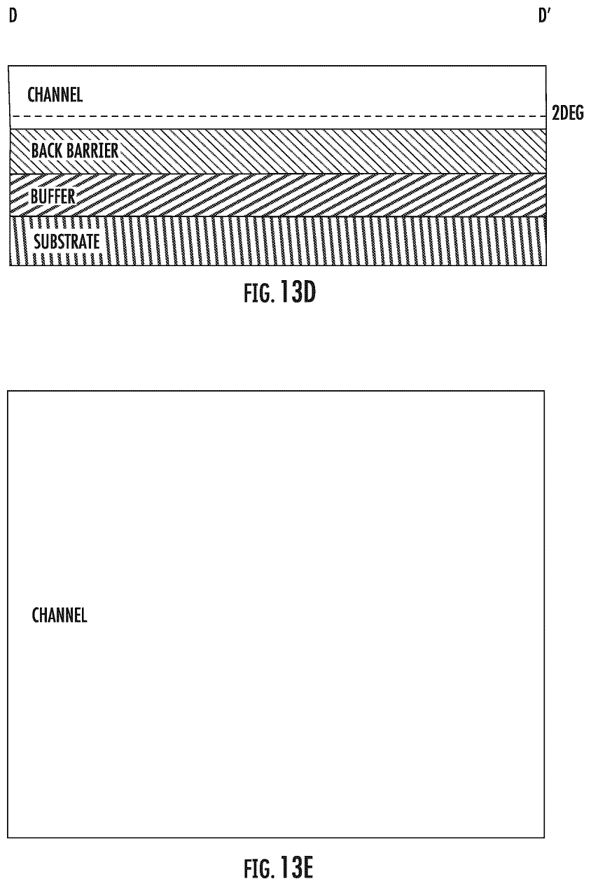

FIGS. 13A-15E illustrate the structure of the device in various stages of the fabrication process. FIGS. 13A-13E show the starting epitaxial structure.

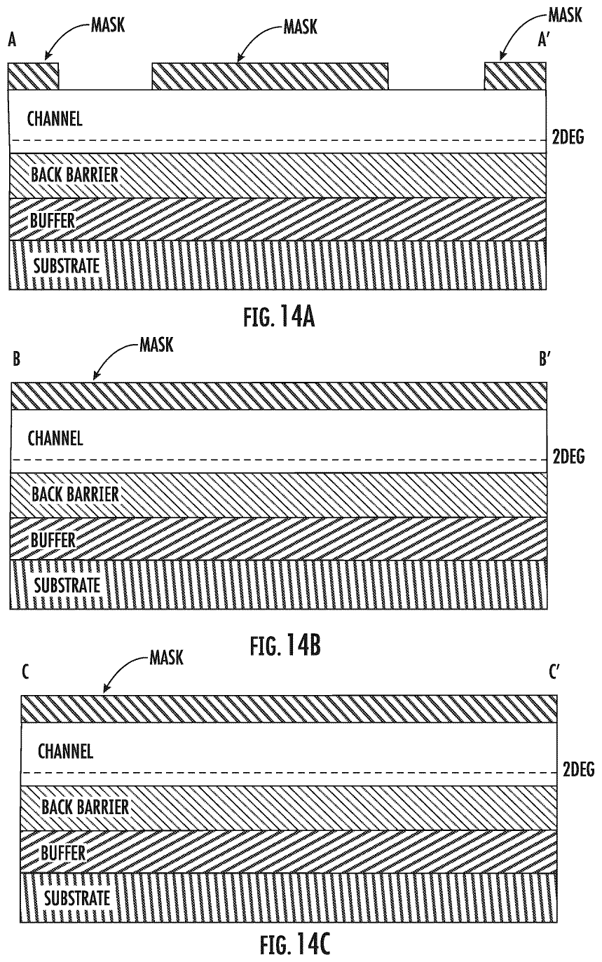

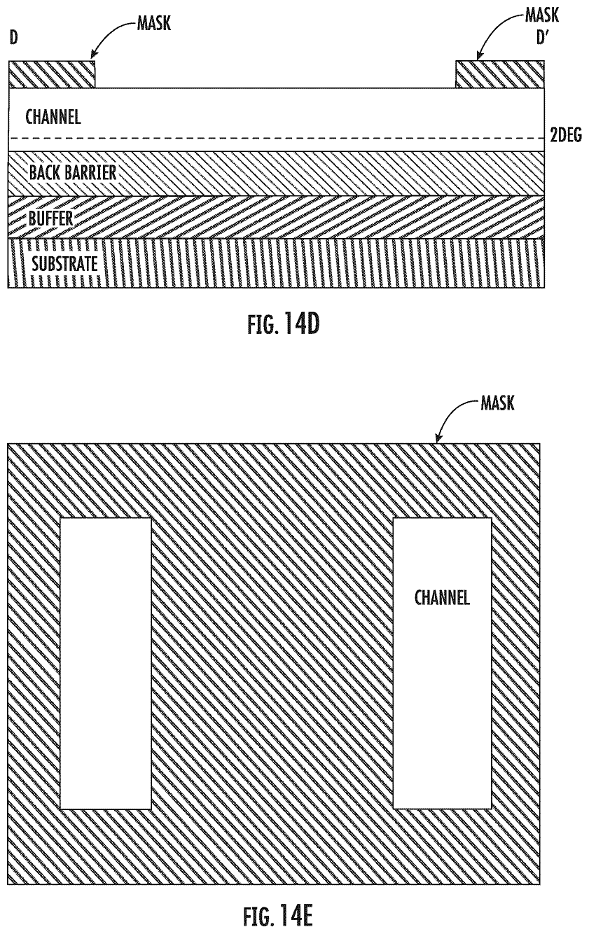

FIGS. 14A-14E illustrate forming a regrowth mask that protects the regions near the active area of the FET except for over the source and drain contact regions. There can also be additional regions away from the FET where there is not a mask in place (i.e., where regrowth will occur) that are not shown. This could be done, e.g., to increase the fill-factor of the regrowth process.

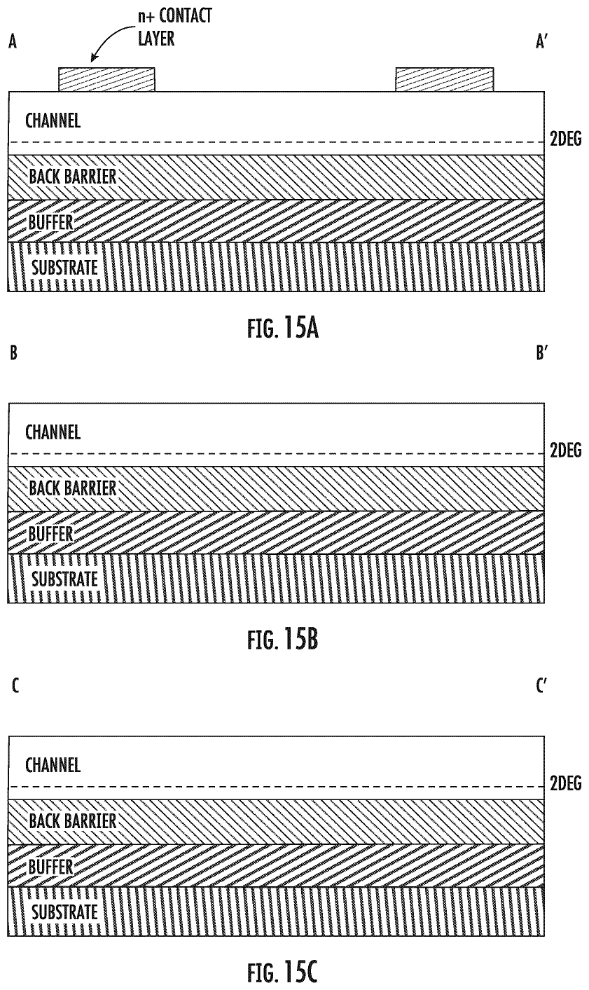

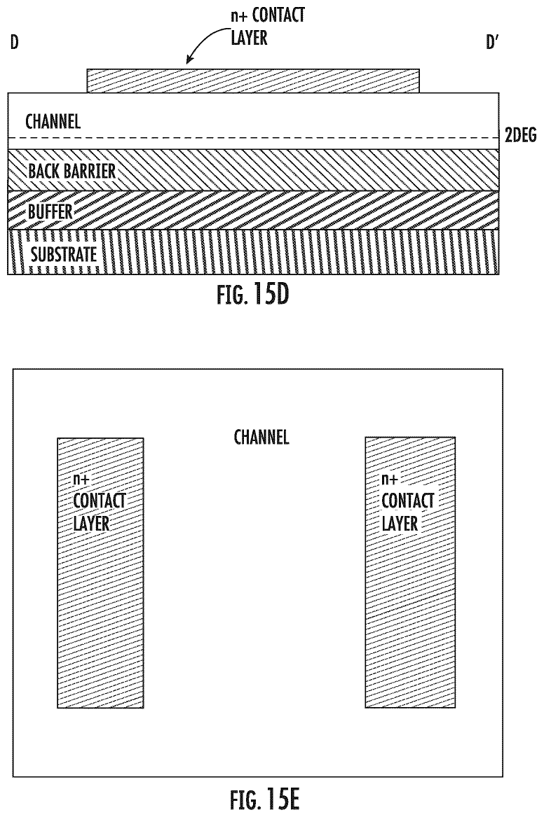

FIGS. 15A-15E illustrate regrowing the n+ GaN contact layer and removing the regrowth mask. The remaining steps are illustrated in FIGS. 6A-12E and described above with references to FIGS. 6A-12E.

The use of in-situ n+ contact layers removes the need for an epitaxial regrowth step from the fabrication process; however, it may introduce challenges in device fabrication due to the need for accurate channel and gate recess etches. Two example approaches for using etch stop layers for the channel recess are described below.

FIG. 16 shows an epitaxial structure comprising an n+ layer as an etch stop. An n+ layer that contains a concentration of free electrons can pin the Fermi level at the conduction band edge which minimizes the concentration of free holes needed for etching to progress. In this structure the top most n+ layer (“contact layer”) is first etched away using an etch that is able to etch n+ GaN (such as a plasma etch) stopping within the UID spacer layer. The n+ contact layer can have any appropriate thickness, for example, a thickness from 2-200 nm, or 5-100 nm. The UID spacer layer can have any appropriate thickness, for example, a thickness from 1-50 nm, or 5-15 nm.

These etches often have a tradespace between etch rate, surface roughness, etch profile (trenching, footing), aspect ratio effects, and uniformity that can make it difficult to obtain the desired etch profile across the entire wafer. These effects, in some cases, tend to get worse the thicker the layer that needs to be etched thru. By including a follow-up selective etch that stops on the n+ GaN etch stop layer the surface morphology can be recovered to be a smooth surface with distances to the 2deg defined epitaxially. Since the n+ etch stop layer can be made thin, it can be removed without significantly disturbing the surface morphology. Once the channel recess is complete the gate recess can be performed. The n+ etch stop layer can have any appropriate thickness, for example, from 0.5-10 nm, or 2-5 nm.

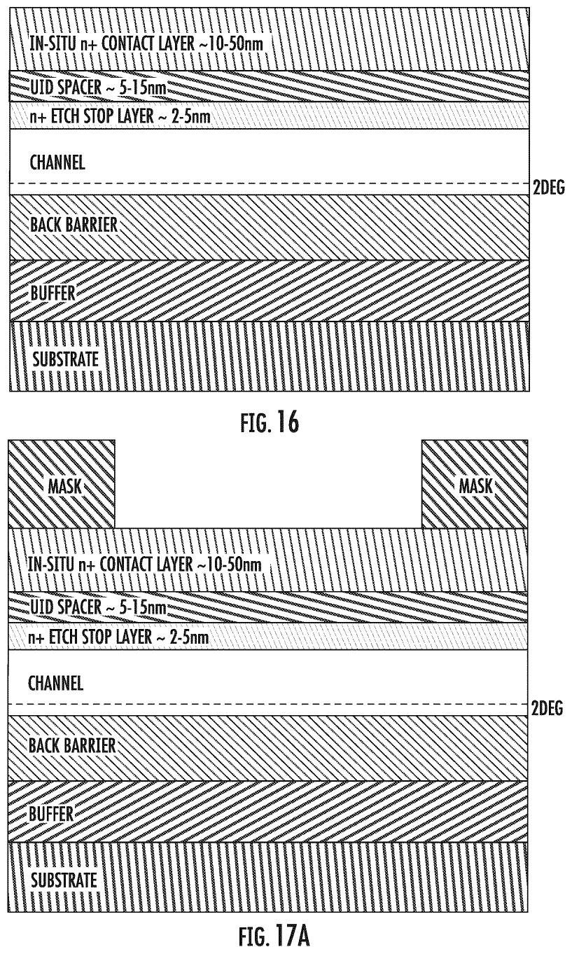

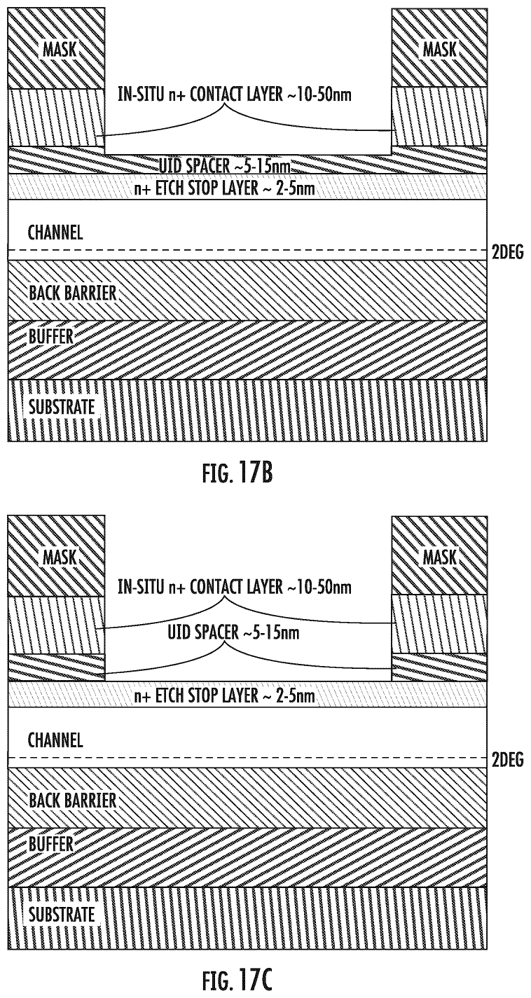

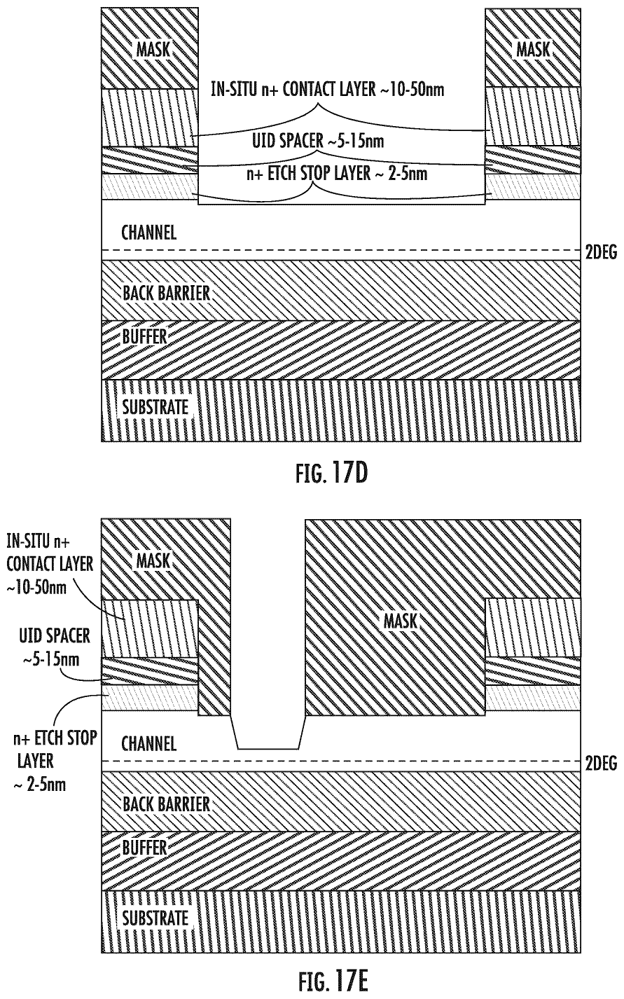

FIGS. 17A-17E illustrate the process flow by showing the device structure at various stages of the process. In the example shown in FIGS. 17A-17E, no electron barrier is introduced due to the use of only n+ and UID layers within the contact layer. In some examples, the process for the channel recess includes:
1. Perform unselective etch (for example, plasma etch) to etch through the n+ contact layer stopping somewhere in the UID spacer layer.
2. Perform selective etch (for example, wet etch) that etches remainder of UID spacer stopping on the n+ spacer layer.
3. Etch through n+ etch stop either using a selective or an unselective etch.
4. Proceed to gate recess etching

Unselective etches can suffer from either trenching or footing where the etch rate near the mask edge is either enhanced or reduced relative to the regions away from the mask edge.

FIG. 17A shows the creation of the mask. FIG. 17B shows the use of the unselective etch. FIG. 17C shows performing the selective etch. FIG. 17D shows performing the etch through the n+ etch stop. FIG. 17E shows the gate recess etching.

In some examples, the devices described in this document can use an AlGaN etch stop layer, for example, an AlGaN etch stop layer or another appropriate type of layer. In general the etch stop layer can be an Al-containing III-N layer. AlGaN etch stop layers, in some cases, have a common drawback within contact structures as the polarization and bandgap differences to GaN results in electron barriers.

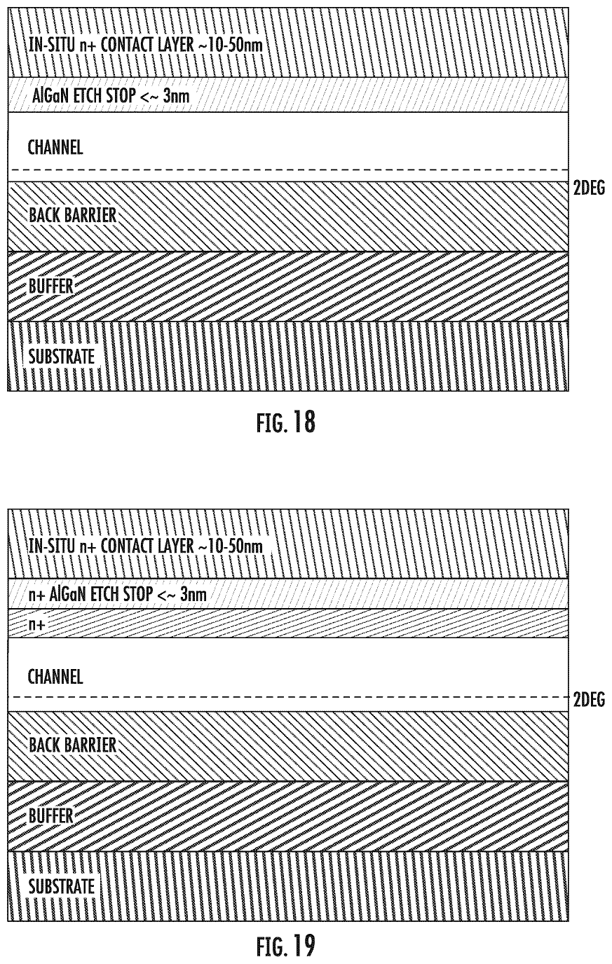

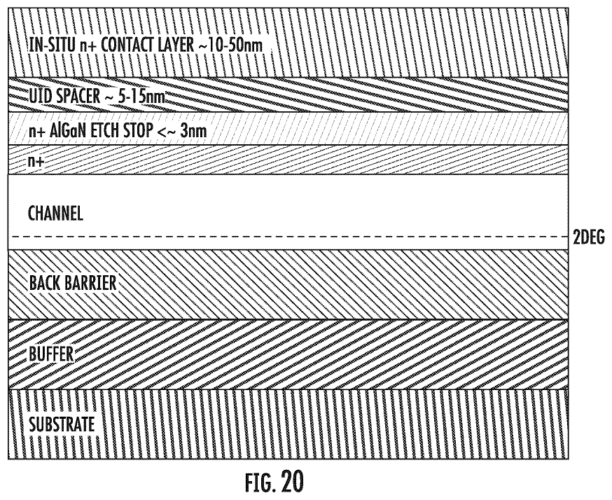

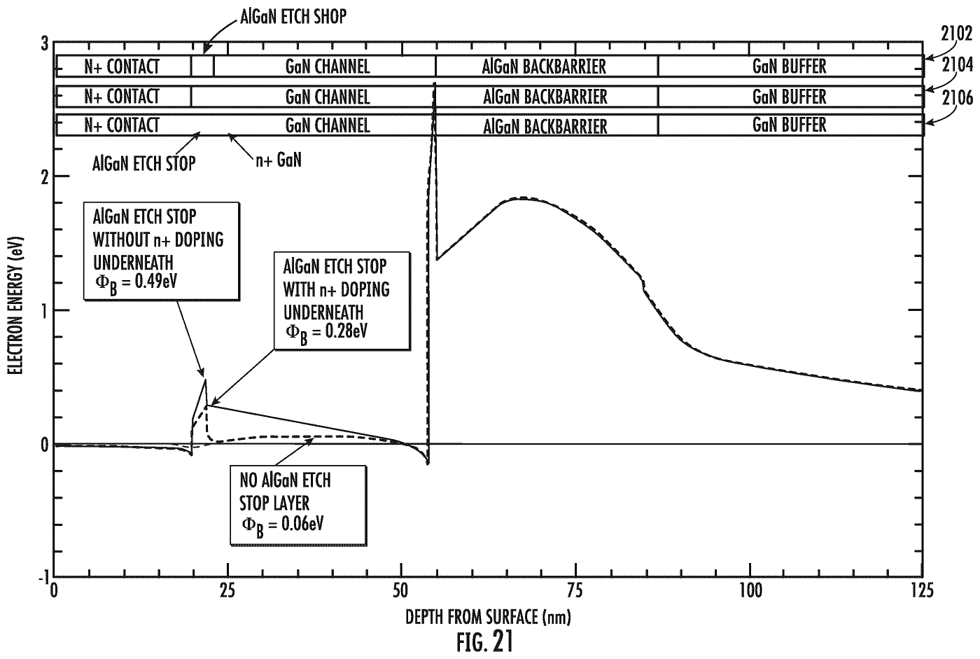

In some examples, a device can include an AlGaN etch stop layer at the bottom of the n+ contact layer. For example, FIG. 18 shows an epitaxial structure that can be used to create a semiconductor device using such a stop layer. FIG. 19 shows a structure with added doping underneath the AlGaN barrier. FIG. 20 shows a structure with a UID spacer layer, e.g., which can be used to get selectivity, e.g., a wet etch that etches the UID but not n+ GaN. FIG. 21 illustrates the AlGaN etch stop options with band diagrams. FIG. 21 shows three curves 2102 (FIG. 18), 2104 (FIGS. 2), and 2106 (FIG. 19).

Adding a 2 nm A10.15Ga0.85N etch stop layer to the bottom of an N+ contact layer introduces a large 0.49 eV barrier due to the N-polar orientation which causes electrons to be depleted from under an AlGaN barrier (FIG. 21, curve 2102). This barrier can be cut in half (0.28 eV) by adding in n+ doping underneath the AlGaN barrier (FIG. 19; FIG. 21, curve 2106). This structure would first use the AlGaN as an etch stop layer followed by the removal of that layer and the underlying n+ layer during the channel recess etch. Furthermore, in some examples, approaches may be combined to get the desired selectivity. N+ layers may show reduced etch rates resulting from the presence of a high free electron density and low free hole density. Therefore, a UID spacer can be introduced above the AlGaN to provide etch selectivity in a 2-part etch described above, as shown in FIG. 20.

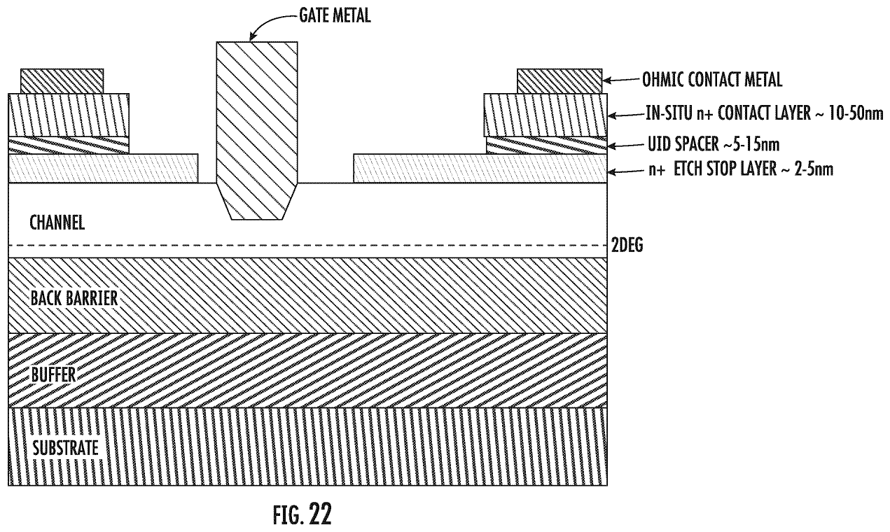

FIG. 22 illustrates a device structure having a thin n+ layer in the access regions. The device can be fabricated from the structure shown in FIG. 16.

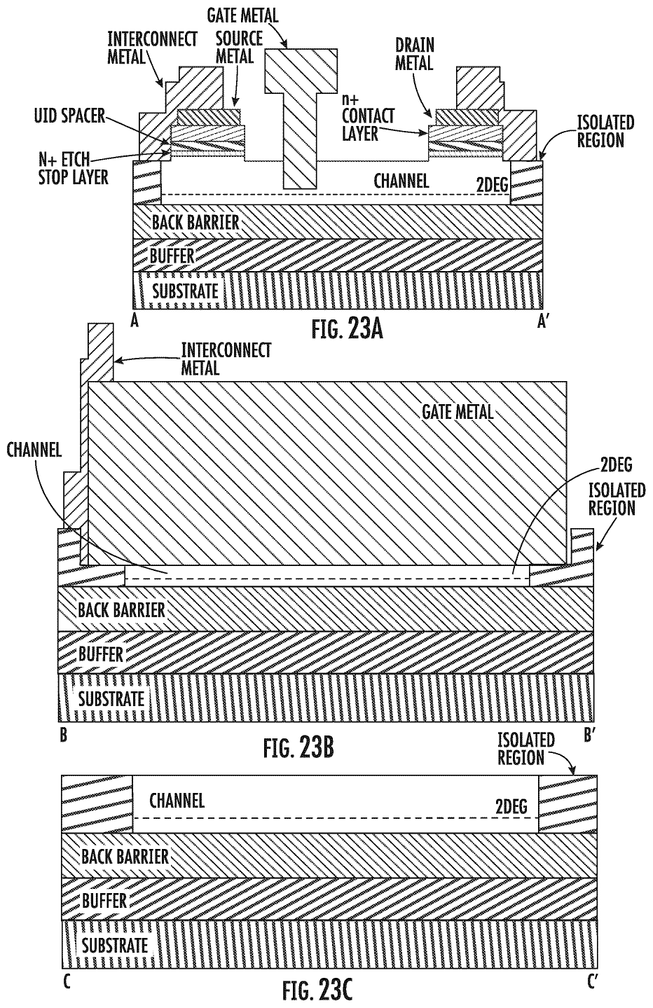

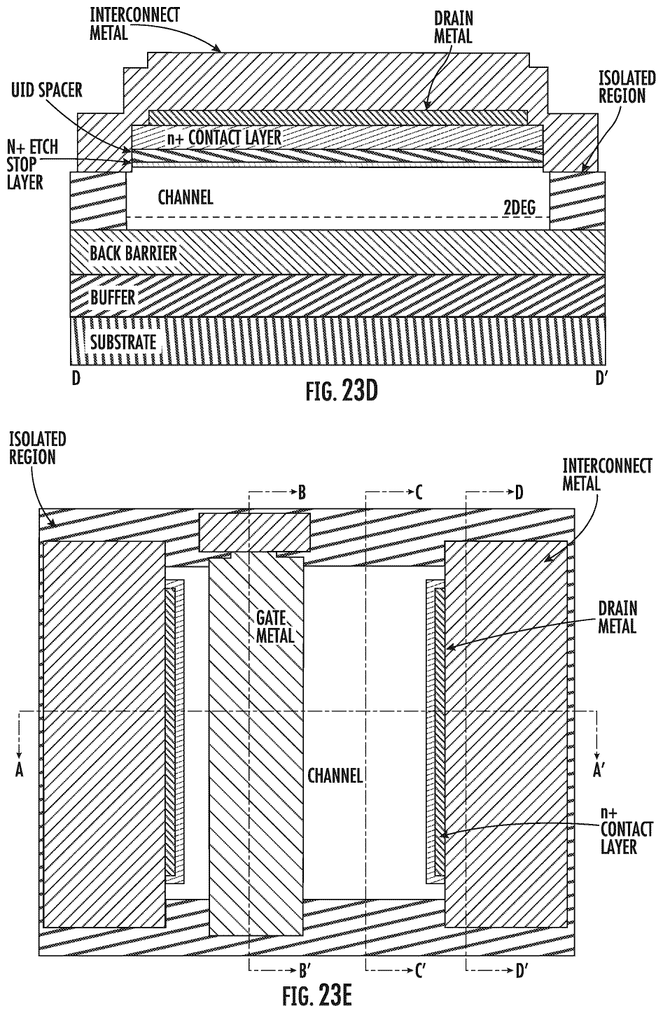

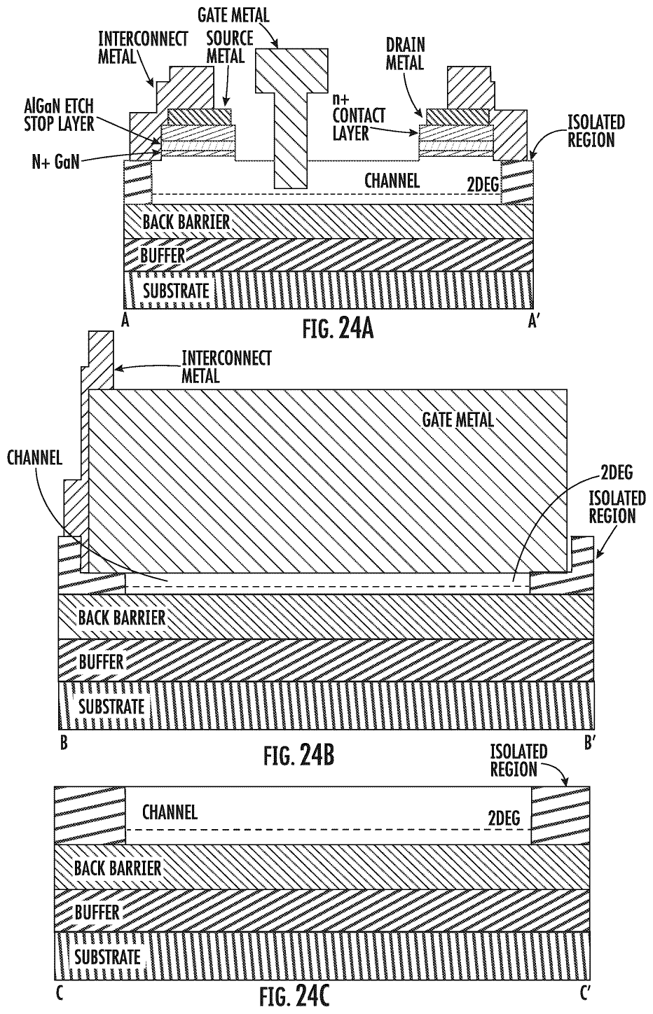

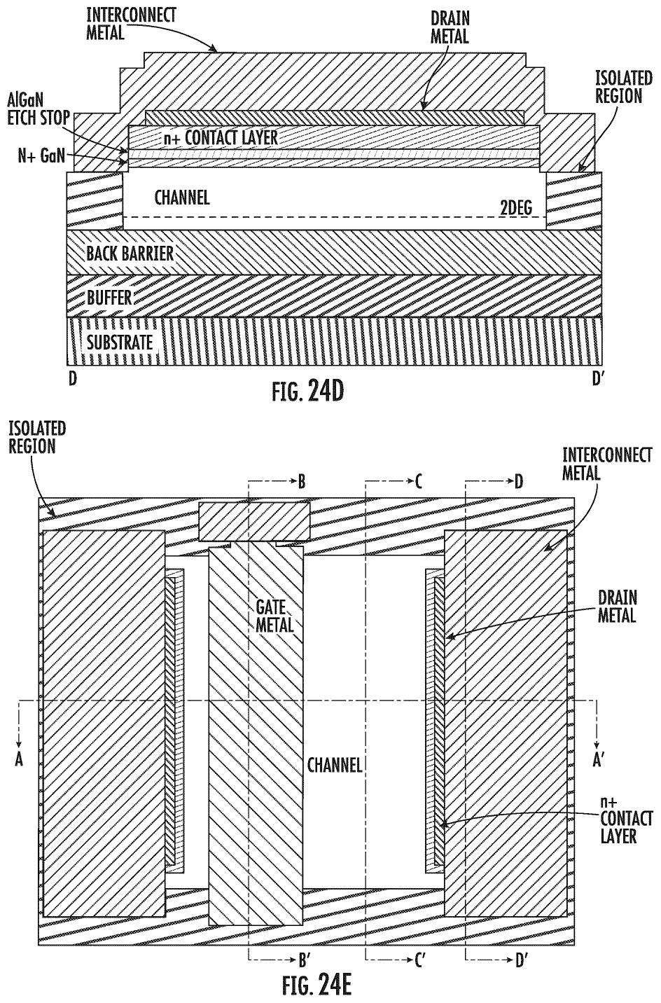

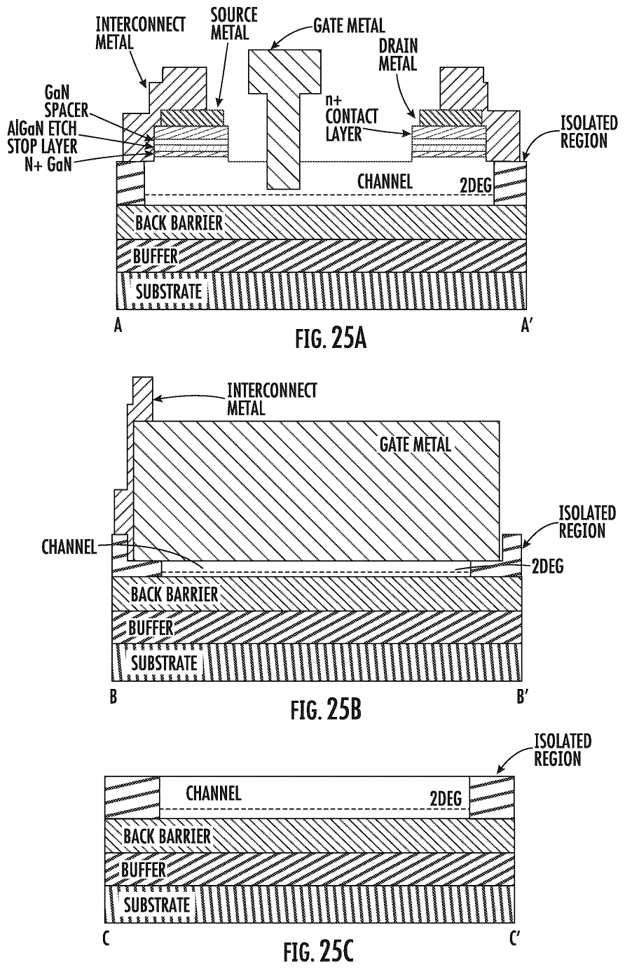

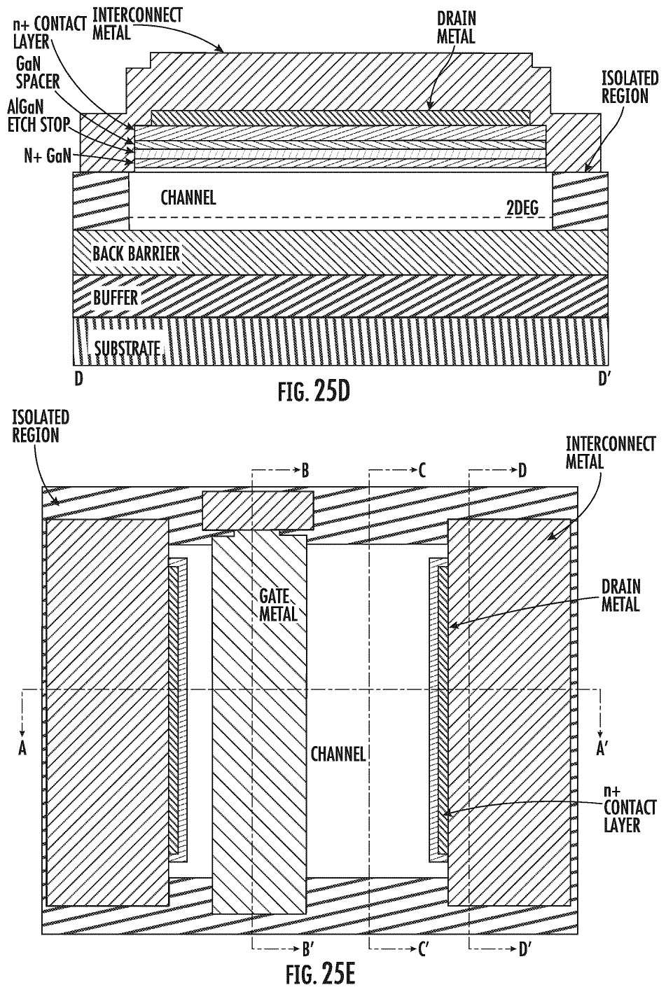

FIGS. 23A-23E show an alternative device fabricated from the structure shown in FIG. 16. FIGS. 24A-24E show a device fabricated from the structure shown in FIG. 19. FIGS. 25A-25E show a device fabricated from the structure shown in FIG. 20.

Various devices and their material structures have been described above. However, it should be understood that they have been presented by way of example only, and not limitation. The implementations have been particularly shown and described, but it will be understood that various changes in form and details may be made. Accordingly, other implementations are within the scope of the following claims.

1. A semiconductor device, comprising:
a III-N material structure, comprising:
a III-N backbarrier layer;
a III-N channel layer over an N-face of the III-N backbarrier layer, the III-N channel layer having a smaller bandgap than the III-N backbarrier layer; and
an n-type III-N layer over an N-face of the III-N channel layer, wherein a donor concentration of the n-type III-N layer is at least 10¹⁸ cm⁻³; and
a non-active region surrounding an active region, the active region comprising a gate region between a source region and a drain region; wherein
the active region comprises the III-N backbarrier layer, the III-N channel layer, the n-type III-N layer, a source contact over the n-type III-N layer in the source region, a drain contact over the n-type III-N layer in the drain region, and a 2DEG in the III-N channel layer adjacent to an interface between the III-N channel layer and the III-N backbarrier layer; and
the semiconductor device further comprises a gate recess in the channel layer and a gate contact in the gate recess, wherein the gate recess is formed across a width of the active region and has a portion formed in the non-active region, the gate contact is formed across the width of the active region and in the portion of the recess that is in the non-active region, the gate recess has a bottom surface, and the bottom surface of the gate recess in the active region and the bottom surface of the gate recess in the non-active region are substantially co-planar.

2. The semiconductor device of claim 1, wherein the n-type III-N layer is in the source and drain regions of the active region but not in the gate region of the active region.

3. The semiconductor device of claim 1, wherein the non-active region comprises the III-N backbarrier layer and the III-N channel layer but not the n-type III-N layer.

4. The semiconductor device of claim 1, wherein, in the non-active region, the III-N channel layer and the III-N backbarrier layer are implanted with ions.

5. The semiconductor device of claim 1, wherein the 2DEG is not in the non-active region.

6. A semiconductor device, comprising:
a III-N material structure, comprising:
a III-N backbarrier layer;
a III-N channel layer over an N-face of the III-N backbarrier layer, the III-N channel layer having a smaller bandgap than the III-N backbarrier layer; and
an n+ III-N etch stop layer over an N-face of the III-N channel layer;
a gate region between a source region and a drain region;
a source contact over the n+ III-N etch stop layer in the source region;
a drain contact over the n+ III-N etch stop layer in the drain region;
a 2DEG in the III-N channel layer adjacent to an interface between the III-N channel layer and the III-N backbarrier layer;
a channel recess etched through the n+ III-N etch stop layer between the source region and the drain region; and
a gate recess in the channel layer and a gate contact in the gate recess.

7. The semiconductor device of claim 6, wherein the n+ III-N etch stop layer is 2-5 nm thick.

8. The semiconductor device of claim 6, wherein the n+ III-N etch stop layer is 0.5-10 nm thick.

9. The semiconductor device of claim 6, comprising a UID spacer layer over the n+ III-N etch stop layer.

10. The semiconductor device of claim 9, wherein the UID spacer layer is 5-15 nm thick.

11. The semiconductor device of claim 9, wherein the UID spacer layer is 0.5-50 nm thick.

12. The semiconductor device of claim 9, comprising an n+ III-N contact layer over the UID spacer layer.

13. The semiconductor device of claim 12, wherein the n+ III-N contact layer is at least 2 nm thick.

14. The semiconductor device of claim 12, wherein the n+ III-N contact layer is 5-100 nm thick.

15. The semiconductor device of claim 6, comprising a non-active region surrounding an active region, the active region comprising the gate region, the III-N backbarrier layer, the III-N channel layer, the n+ III-N etch stop layer, the source contact, the drain contact, and the 2DEG.

16. The semiconductor device of claim 6, wherein the n+ III-N etch stop layer extends into one or more access regions of the semiconductor device.

17. The semiconductor device of claim 6, wherein the gate recess has a bottom surface spanning across an active region and a non-active region, and wherein the bottom surface of the gate recess in the active region and the bottom surface of the gate recess in the non-active region are substantially co-planar.

18. A semiconductor device, comprising:
a III-N material structure, comprising:
a III-N backbarrier layer;
a III-N channel layer over an N-face of the III-N backbarrier layer, the III-N channel layer having a smaller bandgap than the III-N backbarrier layer; and
an Al-containing III-N etch stop layer over an N-face of the III-N channel layer;
a gate region between a source region and a drain region;
a source contact over the Al-containing III-N etch stop layer in the source region;
a drain contact over the Al-containing III-N etch stop layer in the drain region;
a 2DEG in the III-N channel layer adjacent to an interface between the III-N channel layer and the III-N backbarrier layer;
a channel recess etched through the Al-containing III-N etch stop layer between the source region and the drain region; and
a gate recess in the channel layer and a gate contact in the gate recess.

19. The semiconductor device of claim 18, comprising a layer of n+ doping underneath the AlGaN etch stop layer.

20. The semiconductor device of claim 18, wherein the Al-containing III-N etch stop layer is between 2-5 nm thick.

21. The semiconductor device of claim 18, wherein the Al-containing III-N etch stop layer is between 0.5 nm-10 nm thick.

22. The semiconductor device of claim 18, wherein the Al-containing III-N etch stop layer is composed of AlGaN, AlInN, AlGaInN, or AlScN, or any combination thereof.

23. The semiconductor device of claim 18, comprising a UID spacer layer over the Al-containing III-N etch stop layer.

24. The semiconductor device of claim 22, wherein the UID spacer layer is 5-15 nm thick.

25. The semiconductor device of claim 22, wherein the UID spacer layer is at least 1 nm thick.

26. The semiconductor device of claim 22, comprising an n+ III-N contact layer over the UID spacer layer.

27. The semiconductor device of claim 18, wherein the n+ III-N contact layer is 5-100 nm thick.

28. The semiconductor device of claim 18, wherein the n+ III-N contact layer is at least 2 nm thick.

29. The semiconductor device of claim 18, comprising a non-active region surrounding an active region, the active region comprising the gate region, the III-N backbarrier layer, the III-N channel layer, the n+ III-N etch stop layer, the source contact, the drain contact, and the 2DEG.

30. The semiconductor device of claim 27, wherein the gate recess has a bottom surface, and the bottom surface of the gate recess in the active region and the bottom surface of the gate recess in the non-active region are substantially co-planar.

31. (canceled)

32. (canceled)

33. (canceled)
